(19) United States
(12) Patent Application Publication
(10) Pub. No.: US 2013/0193475 A1
(43) Pub. Date: Aug. 1, 2013

(54) SEMIFINISHED PRODUCT AND METHOD FOR PRODUCING A LIGHT-EMITTING DIODE

(71) Applicants: Volker Arning, Dusseldorf (DE); Mikko Meyder, Essen (DE)

(72) Inventors: Volker Arning, Dusseldorf (DE); Mikko Meyder, Essen (DE)

(73) Assignee: Evonik Goldschmidt GmbH, Essen (DE)

(21) Appl. No.: 13/810,151

(22) PCT Filed: Jun. 15, 2011
(86) PCT No.: PCT/EP2011/059907

§ 371 Date: Apr. 15, 2013

(30) Foreign Application Priority Data
Jul. 14, 2010 (DE) 102010031302.5

(51) Int. Cl. H01L 33/62

(52) U.S. Cl. CPC H01L 33/62
USPC 257/99; 438/27

(57) ABSTRACT

The invention relates to a method and a semifinished product for producing a light-emitting diode including: a flexible supporting material; a first and a second contact area, arranged on the supporting material, for producing electrical connections; a light-emitting diode chip or a holder for a light-emitting diode chip, arranged on the supporting material; a foldable flap, formed into the supporting material, the flap being arranged in such a way that it can be folded towards and/or onto the light-emitting diode chip. Arranged on the foldable flap is at least a first electrical connecting web, which is connected to the first contact area and can be connected to a first terminal of the light-emitting diode chip by folding of the flap.

The present application claims priority from PCT Patent Application No. PCT/EP2011/059907 filed on Jun. 15, 2011, which claims priority from German Patent Application No. DE 10 2010 031 302.5 filed on Jul. 14, 2010, the disclosure of which is incorporated herein by reference in its entirety.

### 1. FIELD OF THE INVENTION

The invention relates to a semifinished product and to a method for producing a light-emitting diode.

It is noted that citation or identification of any document in this application is not an admission that such document is available as prior art to the present invention.

In other methods for producing a light-emitting diode, the active elements of the light-emitting diode, known as light-emitting diode chips or dies or chip or dies, are placed on a wire-like H-shaped element. An electrical connection is produced between a first terminal of the light-emitting diode chip and an upper end of the H-shaped element. After that, a second terminal of the light-emitting diode chip is connected to the second upper end of the H-shaped element, for example by the known gold wire bonding method. The upper end of the H-shaped element with the light-emitting diode chip arranged on it is then arranged in a lens casting body, which is filled with a casting compound for producing the lens body. After producing the lens body, the connecting crosspiece of the H-shaped element is removed in a soldering-like process, in order to eliminate the short-circuit.

To increase the luminous efficiency, reflectors may be used, arranged around the light-emitting diode chip before the production of the lens body.

Since light-emitting diode chips do not radiate in all colours, but emit discrete optical wavelengths, for conversion into white light, for example, it is necessary to change the frequency by means of luminescent materials, for example phosphorus. This phosphorus is usually admixed with the casting compound for producing the lens body.

The method described requires high precision in the positioning of the light-emitting diode chip on the H-shaped element. Furthermore it is very laborious to produce the connection between the second terminal of the light-emitting diode chip and the second upper end of the H-shaped element. On account of the complex production method, the production rate of a light-emitting diode by the known method is limited.

It is noted that in this disclosure and particularly in the claims and/or paragraphs, terms such as “comprises”, “comprised”, “comprising” and the like can have the meaning attributed to it in. U.S. Patent law; e.g., they can mean “includes”, “included”, “including”, and the like; and that terms such as “consisting essentially of” and “consists essentially of” have the meaning ascribed to them in U.S. Patent law, e.g., they allow for elements not explicitly recited, but exclude elements that are found in the prior art or that affect a basic or novel characteristic of the invention.

It is further noted that the invention does not intend to encompass within the scope of the invention any previously disclosed product, process of making the product or method of using the product, which meets the written description and enablement requirements of the USPTO (35 U.S.C. 112, first paragraph) or the EPO (Article 83 of the EPC), such that applicant(s) reserve the right to disclaim, and hereby disclose a disclaimer of, any previously described product, method of making the product, or process of using the product.

### SUMMARY OF THE INVENTION

The invention is based on the object of providing a simple and quick production method for light-emitting diodes.

The object is achieved by a semifinished product for producing a light-emitting diode comprising a flexible supporting material, a first and a second contact area, arranged on the supporting material, for producing electrical connections, a light-emitting diode chip or a holder for a light-emitting diode chip, arranged on the supporting material, a foldable flap, formed into the supporting material, the flap being arranged in such a way that it can be folded towards and/or onto the light-emitting diode chip, there being arranged on the foldable flap at least a first electrical connecting web, which is connected to the first contact area and can be connected to a first terminal of the light-emitting diode chip by folding of the flap.

The use of a semifinished product according to the invention in the production of a light-emitting diode has the advantage that the foldable flap which is formed into the supporting material and on which there is arranged a first electrical connecting web, which is connected to the first contact area and can be connected to a first terminal of the light-emitting diode chip by folding of the flap, makes it possible to produce an electrically conductive connection between a contact area of the semifinished product and a terminal of the light-emitting diode chip simply and quickly. As a result, the rate of the process of producing the light-emitting diode is significantly improved.

According to an exemplary embodiment of the invention, the second contact area is connected to a second terminal of the light-emitting diode chip by way of a second electrical connecting web. The electrically conductive connection between the second contact area and the second terminal of the light-emitting diode chip is produced when the light-emitting diode chip is applied to the semifinished product. Consequently, in the subsequent process of producing the light-emitting diode, only an electrically conductive connection between the first contact area and the first terminal of the light-emitting diode chip has to be produced.

According to an alternative embodiment of the invention, on the foldable flap there is arranged a second electrical connecting web, which is connected to the second contact area and can be connected to the second terminal of the light-emitting diode chip by folding of the flap. It is consequently possible in one production step to produce the electrically conductive connections between the first contact area and the first terminal of the light-emitting diode chip and between the second contact area and the second terminal of the light-emitting diode chip, whereby the production rate of a light-emitting diode is further improved.

With both connecting webs arranged on the foldable flap, the flexible supporting material is expediently essentially transparent in the region of the holder for the light-emitting diode chip with respect to the radiation emitted by the light-emitting diode chip, so that the radiation emitted by the light-emitting diode chip is radiated through the semifinished product and the connecting webs are folded onto the rear side of the light-emitting diode chip by means of the flap.

The underlying object of the invention is also achieved by a semifinished product for producing a light-emitting diode comprising a flexible supporting material, a first and a second contact area, arranged on the supporting material, for producing electrical connections, a first and a second electrical connecting web on the supporting material, which webs are respectively connected to the first and second contact areas, a foldable flap, formed into the supporting material, a light-emitting diode chip, arranged on the flap, or a holder for a light-emitting diode chip, arranged on the flap, the flap and the first and second connecting webs being arranged in such a way that a first and a second terminal of the light-emitting diode chip are respectively connected to the first and second connecting webs by folding of the flap. This achieves the effect that, when the flap is folded, the first and second terminals of the light-emitting diode chip are respectively connected in an electrically conductive manner to the first and second connecting webs. Since the positions of the light-emitting diode chip and of the first and second connecting webs are predetermined, a simple and quick connection between the terminals of the light-emitting diode chip and the contact areas of the semifinished product can be produced in this way.

After the folding, the flap of one of the semifinished products described above is expediently fixed to the light-emitting diode chip by an adhesive.

According to an advantageous embodiment of the invention, the adhesive contains phosphorus compounds, in order to convert the frequency of the radiation radiated by the light-emitting diode chip. Since light-emitting diodes emit discrete optical wavelengths and do not radiate in all colours, for the conversion of the radiation given off it is desirable to change the frequency, for example by means of phosphorus. This has the advantage that the phosphorus compounds are not integrated in the lens body, as known from the prior art, but merely in the adhesive layer between the flap and the light-emitting diode chip, thereby reducing the amount of phosphorus compounds required.

The flap of one of the semifinished products described above is expediently at least partially transparent with respect to the radiation emitted by the light-emitting diode chip.

According to a further advantageous configuration of the invention, the flap contains phosphorus compounds, in order to convert the frequency of the radiation radiated by the light-emitting diode chip. This allows the frequency of the radiation radiated by the light-emitting diode chip to be converted to the desired frequency in a simple way.

A reflector for the radiation radiated by the light-emitting diode chip is advantageously arranged on the flap, for example by placement, vapour deposition or sputtering of aluminium. This increases the luminous efficiency of the light-emitting diode. It also avoids an additional method step in which an additional reflector is arranged in the vicinity of the light-emitting diode chip.

The first and second contact areas are expediently respectively connected to a contact pin. These contact pins serve for producing an electrically conductive connection to an external electronic circuit, in which the light-emitting diode is fitted. For example, for this purpose the contact pins are arranged approximately parallel to one another at a specific distance from one another, for example at a distance of 3 mm or 5 mm.

According to an alternative embodiment of the invention, the first and/or second contact area arranged on the supporting material can be deformed into a contact pin, preferably by means of folding lines provided on the supporting material The folding of the supporting material along the folding lines has the effect that the first and/or second contact area arranged on the supporting material is deformed into a contact pin, thereby avoiding the connection of the first and/or second contact area to a separate contact pin.

According to a preferred embodiment of the invention, one of the semifinished products described above comprises multiple light-emitting diode chips and/or holders for light-emitting diode chips, preferably two to eight light-emitting diode chips and/or holders for light-emitting diode chips. The arrangement of multiple light-emitting diode chips on a semifinished product according to the invention allows the intensity of the radiation that is given off to be increased. It is also possible to convert the radiation that is given off by the multiple light-emitting diode chips differently by the use of different phosphorus compounds, so that different colours can be radiated, or to combine light-emitting diode chips that emit different colours, such as for example in the case of so-called RGB LEDs.

If the semifinished product has multiple light-emitting diode chips and/or holders for light-emitting diode chips, the semifinished product may likewise comprise multiple foldable flaps formed into the supporting material, the flaps being arranged in such a way that they can be respectively folded towards and/or onto one of the light-emitting diode chips. This is particularly advantageous if the radiation given off by the individual light-emitting diode chips is intended to be converted by means of phosphorus compounds in the adhesive between the flap and the light-emitting diode chip or within the flap.

The object underlying the invention is also achieved by a method for producing a light-emitting diode comprising the steps of: providing one of the semifinished products described above, folding the flap, possibly applying the contact pins to the contact areas, arranging the semifinished product in a lens casting body and filling the lens casting body with a casting compound for producing a lens body. The method according to the invention has the advantage that the production of the electrical connection between the light-emitting diode chip and the contact areas of the semifinished product is produced by simple folding of the flap, and consequently avoids using the laborious gold wire bonding method for producing the electrically conductive connection between the light-emitting diode chip and the contact areas of the semifinished product.

Before the folding of the flap, an adhesive is expediently applied to the flap or the light-emitting diode chip, so that the folded flap is fixed.

According to a preferred embodiment of the invention, the semifinished product is deformed in such a way that the contact pins connected to the contact areas are arranged approximately parallel to one another at a specific distance from one another, preferably 3 mm or 5 mm (or 1/10″ or 2/10″). Since the semifinished product consists of a flexible supporting material, it can be easily deformed into the desired form, which makes it easier for the light-emitting diode produced according to the method to be fitted into an external electronic circuit.

For the purposes of the invention, flexible means here that the supporting material can be bent at least by 90° without being permanently damaged.

The contact pins are expediently soldered or adhesively bonded conductively to the contact areas.

Alternatively, the contact pins are connected to the contact areas mechanically, for example by means of a frictional connection and/or by deforming contact regions on the contact pins.

According to a further preferred embodiment of the invention, a sheet has multiple semifinished products described above, the multiple semifinished products being punched out in a further method step, for example before the contact pins are applied to the contact areas, before the semifinished product is arranged in a lens casting body or before the semifinished products are deformed. This allows multiple light-emitting diodes to be produced simultaneously, whereby the production rate is further increased.

For the purposes of the invention, a sheet may also be a web of material, which may possibly be wound onto one or more rolls.

According to an advantageous configuration of the invention, the light-emitting diode chip is arranged in the holder for the light-emitting diode chip by means of the following method: applying an adhesive-repellent composition to at least a sub-surface of the semifinished product that is not the holder for the light-emitting diode chip, curing the adhesive-repellent composition, applying an adhesive composition to the holder for the light-emitting diode chip, the sub-surface of the semifinished product that is provided with the adhesive-repellent composition enclosing and bordering the holder for the light-emitting diode chip that is provided with the adhesive composition, and applying the light-emitting diode chip to the adhesive composition located in the holder for the light-emitting diode chip, the adhesive-repellent composition being a radiation-curing nonstick coating compound. An adhesive composition is understood in the present case as essentially meaning a composition of a nonmetallic substance that is capable of connecting the semifinished product and the light-emitting diode chip by surface-area bonding (adhesion) and internal strength (cohesion). More preferably, the adhesive composition is curable, i.e. it can be crosslinked by suitable measures that arc known per se to a person skilled in the art, resulting in a solid mass that immobilizes the light-emitting diode chip on the semifinished product.

An adhesive-repellent composition is not spontaneously miscible with the adhesive composition and, in contact with it, leads to an increase in the contact angle (wetting angle) between the semifinished product and the adhesive composition. An adhesive-repellent composition of this type is also referred to as a “nonstick coating compound”. The adhesive-repellent composition used according to the invention is a radiation-curing nonstick coating compound, i.e. a nonstick coating compound which has crosslinked or polymerizable radicals that are curable by electromagnetic radiation, in particular UV light or electron radiation. The curing of the adhesive-repellent composition consequently takes place by the composition that is applied to the semifinished product being irradiated with electromagnetic radiation, in particular UV light or electron radiation, until at least partial curing of the composition is achieved, whereby a high pattern fidelity is achieved.

In the case of the method according to the invention, the adhesive composition and the adhesive-repellent composition are applied to the semifinished product in such a way that, after it has cured, the adhesive-repellent composition encloses and borders the adhesive composition once the two compositions have been applied, i.e. the cured adhesive-repellent composition surrounds the adhesive composition located on the semifinished product in such a way that, essentially at every location at which the contact angle forms between the semifinished product and the adhesive composition, there is also a phase boundary of the adhesive composition and the cured adhesive-repellent composition.

The invention also relates to a light-emitting diode containing at least one light-emitting diode chip that has been produced by the method described.

### BRIEF DESCRIPTION OF THE DRAWINGS

FIG. 1 shows a semifinished product according to the invention;

FIG. 2 shows the semifinished product as shown in FIG. 1 after folding of the flap;

FIG. 3 shows the semifinished product as shown in FIG. 2 with applied contact pins;

FIG. 4 shows the semifinished product as shown in FIG. 3 after a deformation of the semifinished product;

FIG. 5 shows a light-emitting diode produced by the method according to the invention;

FIG. 6 shows an alternative connection according to the invention between the first contact area and the second contact area of the semifinished product by connecting pins;

FIG. 7 shows a semifinished product according to the invention after production of the frictional connection;

FIG. 8 shows a semifinished product according to the invention after bending over of the contact pins;

FIG. 9 shows an alternative light-emitting diode according to the invention,

FIG. 10 shows an alternative semifinished product according to the invention; and

FIG. 11 shows a further semifinished product according to the invention.

### DETAILED DESCRIPTION OF EMBODIMENTS

It is to be understood that the figures and descriptions of the present invention have been simplified to illustrate elements that are relevant for a clear understanding of the present invention, while eliminating, for purposes of clarity, many other elements which are conventional in this art. Those of ordinary skill in the art will recognize that other elements arc desirable for implementing the present invention. However, because such elements are well known in the art, and because they do not facilitate a better understanding of the present invention, a discussion of such elements is not provided herein.

The present invention will now be described in detail on the basis of exemplary embodiments.

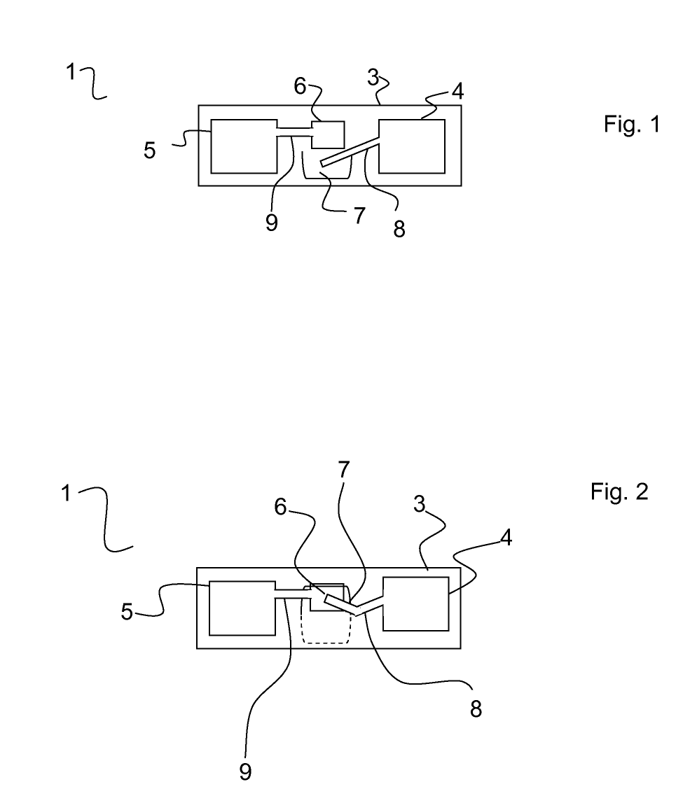

In FIG. 1, a semifinished product 1 for producing a light-emitting diode 2 is represented. The semifinished product 1 comprises a flexible supporting material 3, a first and a second contact area 4, 5, arranged on the supporting material 3, for producing electrical connections, a light-emitting diode chip 6, arranged on the supporting material 3, a foldable flap 7, formed into the supporting material 3, the flap 7 being arranged in such a way that it can be folded onto or against the light-emitting diode chip 6, there being arranged on the foldable flap 7 at least a first electrical connecting web 8, which is electrically connected to the first contact area 4 and can be connected to a first terminal of the light-emitting diode chip by folding of the flap 7. The second contact area 5 is electrically connected to a second terminal of the light-emitting diode chip by way of a second electrical connecting web 9.

A reflector (not represented) for the radiation given off by the light-emitting diode chip 6 is arranged on the flap 7 by vapour deposition of aluminium.

A method according to the invention for producing a light-emitting diode 2 on the basis of a semifinished product 1 as shown in FIG. 1 is explained in more detail below with reference to FIGS. 2 to 5.

During the method according to the invention, an adhesive is applied to the flap 7 or the light-emitting diode chip 6. The adhesive preferably contains phosphorus compounds, in order to convert the frequency of the radiation given off by the light-emitting diode chip 6 to adapt the radiation given off by the light-emitting diode.

After that, the flap 7 is folded onto the light-emitting diode 6. By means of the adhesive applied, the flap 7 is fixed on the light-emitting diode chip 6 after the folding. The flap 7 is at least partially transparent with respect to the radiation emitted by the light-emitting diode chip 6. The semifinished product 1 after folding of the flap 7 onto the light-emitting diode chip 6 is represented in FIG. 2.

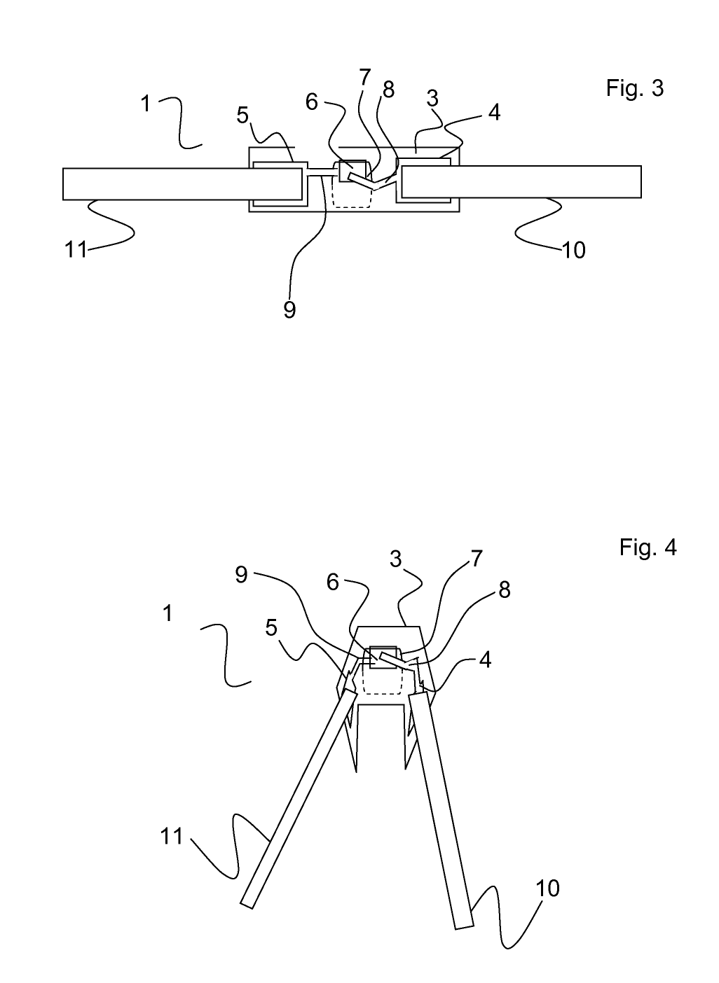

After that, the first contact area 4 and the second contact area 5 are respectively connected to a contact pin 10, 11, for example by soldering. A semifinished product 1 with contact pins 10, 11 is represented in FIG. 3. Subsequently, the semifinished product 1 is deformed in such a way that the contact pins 10, 11 connected to the contact areas 4, 5 are arranged approximately parallel to one another at a specific distance from one another. The distance between the contact pins 10, 11 is preferably 3 mm or 5 mm or they are adapted to the customary pitches of 1/10″ or 2/10″.

In FIG. 4, a semifinished product 1 during the deformation is represented.

The semifinished product 1 deformed in this way is arranged in a lens casting body, which is subsequently filled with a casting compound for producing a lens body 12. After the curing of the casting compound, the finished light-emitting diode 2 can be removed from the lens casting body.

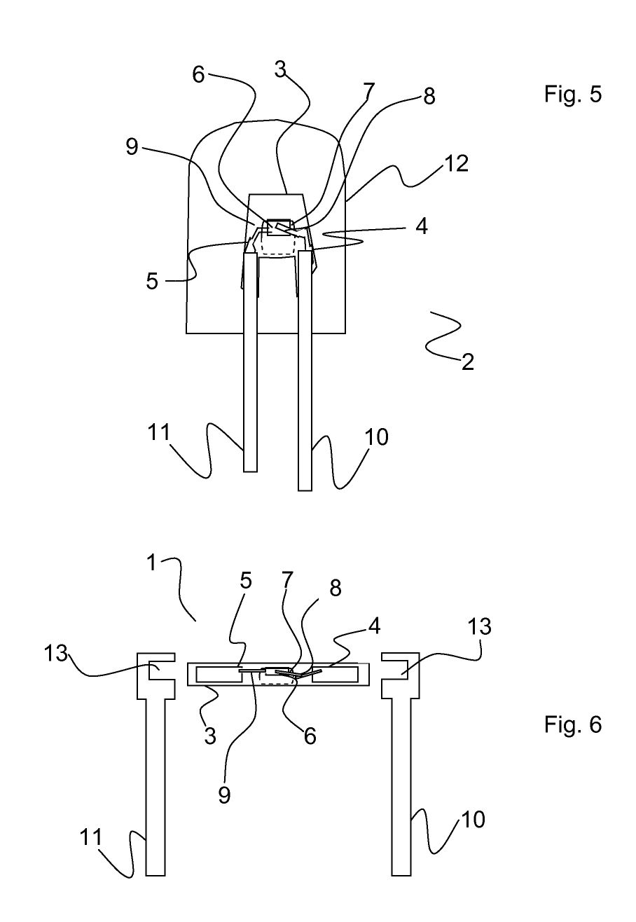

A light-emitting diode 2 produced by the method according to the invention is represented in FIG. 5.

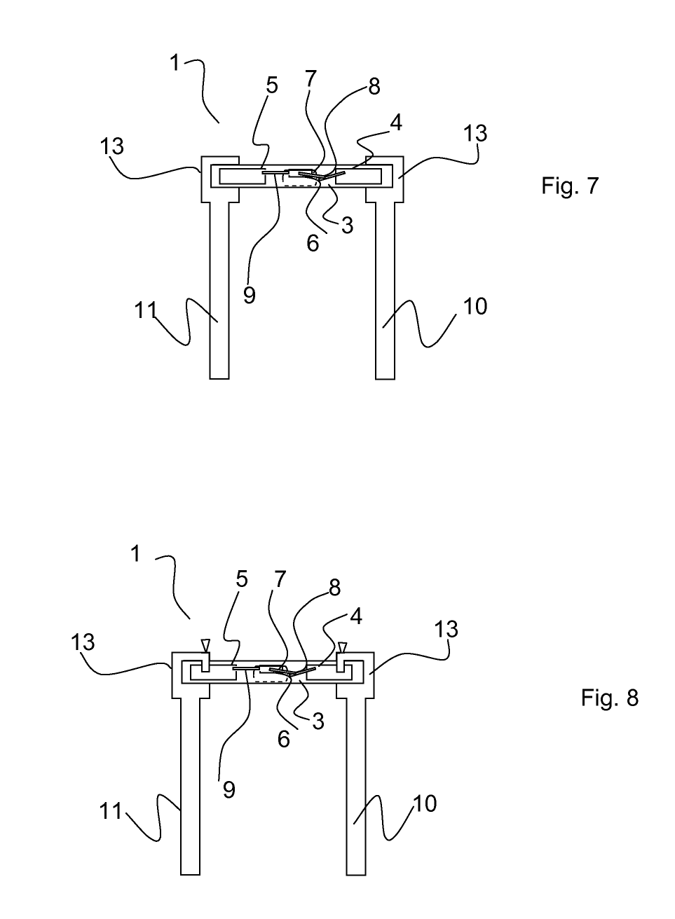

In FIGS. 6-9, an alternative connection between the first contact area 4 and the second contact area 5 of the semifinished product by connecting pins 10, 11 is represented. Contact pins 10, 11 respectively have a recess 13, which is formed in such a way that a frictional connection is respectively produced between the contact pins 10, 11 and the first and second contact areas 4, 5 of the semifinished product. A semifinished product 1 after production of the frictional connection is represented in FIG. 7.

In order to increase further the connection between the contact pins 10, 11 and the semifinished product 1, the contact pins 10, 11 are bent over in the region of the contact areas 4, 5 and the recesses 13, as represented in FIG. 8.

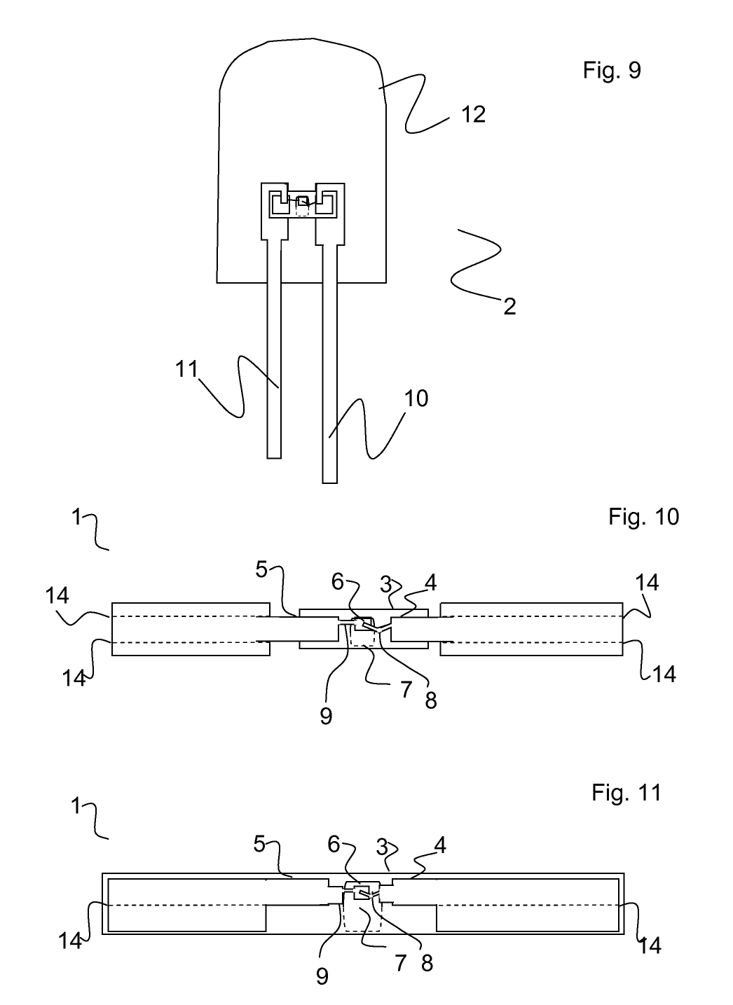

A resultant light-emitting diode 2 is represented in FIG. 9.

In FIG. 10, an alternative semifinished product 1 according to the invention for producing a light-emitting diode 2 is represented. The semifinished product 1 comprises a flexible supporting material 3, a first and a second contact area 4, 5, arranged on the supporting material 3, for producing electrical connections, a light-emitting diode chip 6, arranged on the supporting material, and also a foldable flap 7, formed into the supporting material 3. The flap is arranged in such a way that it can be folded onto or against the light-emitting diode chip 6, there being arranged on the foldable flap 7 at least a first electrical connecting web 8, which is electrically connected to the first contact area 4 and can be connected to a first terminal of the light-emitting diode chip 6 by folding of the flap 7. The second contact area 5 is electrically connected to a second terminal of the light-emitting diode chip 6 by way of a second electrical connecting web 9. The first and second contact areas 4, 5, arranged on the supporting material 3, can be respectively deformed into a contact pin 10, 11. By respective folding of the first and second contact areas 4, 5, arranged on the supporting material 3, along folding lines 14, a contact pin 10, 11 for producing electrical connections is respectively obtained. The folded contact areas 4, 5 are expediently fixed in the folded position by means of an adhesive.

To identify the terminals of the light-emitting diode chip 6, it is possible for example for one of the contact pins 10, 11 to be made shorter.

The semifinished product 1 for producing a light-emitting diode 2 as shown in FIG. 11 differs from the semifinished product as shown in FIG. 10 in that merely one folding line 14 is provided, the width of the part to be folded corresponding essentially to the width of the resultant contact pin 10, 11. An advantage of this is that merely one folding operation has to be carried out.

While this invention has been described in conjunction with the specific embodiments outlined above, it is evident that many alternatives, modifications, and variations will be apparent to those skilled in the art. Accordingly, the preferred embodiments of the invention as set forth above are intended to be illustrative, not limiting. Various changes may be made without departing from the spirit and scope of the inventions as defined in the following claims.

### LIST OF DESIGNATIONS

1—semifinished product

2—light-emitting diode

3—supporting material

4—first contact area

5—second contact area

6—light-emitting diode chip

7—flap

8—first electrical connecting web

9—second electrical connecting web

10—contact pin

11—contact pin

12—lens body

13—recess

14—folding line

1. A semifinished product for producing a light-emitting diode comprising:
a flexible supporting material;
a first and a second contact area, arranged on the supporting material, configured to produce electrical connections;
a light-emitting diode chip or a holder for a light-emitting diode chip, arranged on the supporting material;
a foldable flap, formed into the supporting material, the flap being arranged in such a way that it is foldable towards and/or onto the light-emitting diode chip; and
at least a first electrical connecting web, arranged on the foldable flap, which is connected to the first contact area and is configured to be connected to a first terminal of the light-emitting diode chip by folding of the flap.

2. The semifinished product according to claim 1,
wherein the second contact area is connected to a second terminal of the light-emitting diode chip by way of a second electrical connecting web.

3. The semifinished product according to claim 1, further comprising:
a second electrical connecting web, arranged on the foldable flap, which is connected to the second contact area and is configured to be connected to a second terminal of the light-emitting diode chip by folding of the flap.

4. A semifinished product for producing a light-emitting diode comprising:
a flexible supporting material;
a first and a second contact area, arranged on the supporting material, configured to produce electrical connections;
a first and a second electrical connecting web arranged on the supporting material, the electrical connecting webs being respectively connected to the first and second contact areas;
a foldable flap, formed into the supporting material; and
a light-emitting diode chip, arranged on the flap, or a holder for a light-emitting diode chip, arranged on the flap;
wherein the flap and the first and second connecting webs are arranged in such a way that a first and a second terminal of the light-emitting diode chip are respectively connected to the first and second connecting webs by folding of the flap.

5. The semifinished product according to one of claims 1 and 4;
wherein the flap is fixed on the light-emitting diode chip by an adhesive after the folding.

6. The semifinished product according to claim 5;
wherein the adhesive contains phosphorus compounds, in order to convert the frequency of the radiation radiated by the light-emitting diode chip.

7. The semifinished product according to one of claims 1 and 4;
wherein the flap is at least partially transparent with respect to the radiation emitted by the light-emitting diode chip.

8. The semifinished product according to one of claims 1 and 4;
wherein the flap contains phosphorus compounds, in order to convert the frequency of the radiation radiated by the light-emitting diode chip.

9. The semifinished product according to one of claims 1 and 4, further comprising:
a reflector, configured to reflect the radiation radiated by the light-emitting diode chip, which is arranged on the flap.

10. The semifinished product according to one of claims 1 and 4;
wherein the first and second contact areas are respectively connected to a contact pin.

11. The semifinished product according to one of claims 1 and 4;
wherein the first and/or second contact area, arranged on the supporting material are configured to be deformed into a contact pin.

12. The semifinished product according to one of claims 1 and 4, further comprising:
multiple light-emitting diode chips and/or holders for light-emitting diode chips.

13. The semifinished product according to claim 12, further comprising;
multiple foldable flaps, formed into the supporting material, the flaps being arranged in such a way that they can be respectively folded towards and/or onto one of the light-emitting diode chips.

14. A method for producing a light-emitting diode, comprising the steps of:
providing a semifinished product according to one of claims 1 and 4;
folding the flap;
optionally applying the contact pins to the contact areas arranging the semifinished product in a lens casting body; and
filling the lens casting body with a casting compound for producing a lens body.

15. The method according to claim 14;
wherein an adhesive is applied to the flap or the light-emitting diode chip.

16. The method according to claim 14;
wherein the semifinished product being is deformed in such a way that the contact pins connected to the contact areas are arranged approximately parallel to one another at a specific distance from one another, preferably 3 mm or 5 mm.

17. The method according to claim 14;
wherein the contact pins are soldered to the contact areas.

18. The method according to claim 14;
wherein the contact pins are connected to the contact areas electrically and mechanically.

19. The method according t0 claim 14, further comprising:
providing a sheet having multiple semifinished products according to one of claims 1 and 4, by punching out the multiple semifinished products.

20. The method according to claim 14, further comprising:
arranging the light-emitting diode chip in the holder for the light-emitting diode chip by means of the following method:
applying an adhesive-repellent composition to at least a sub-surface of the semifinished product, which surrounds the holder for the light-emitting diode chip;
curing the adhesive-repellent composition;
applying an adhesive composition to the holder for the light-emitting diode chip; and
applying the light-emitting diode chip the adhesive composition located in the holder for the light-emitting diode chip, the adhesive-repellent composition being a radiation-curing nonstick coating compound;
wherein the sub-surface of the semifinished product that is provided with the adhesive-repellent composition encloses and boarders the holder for the light-emitting diode chip that is provided with the adhesive composition.

21. Light-emitting diode comprising:
at least one light-emitting diode chip, that is produced by the method according to claim 14.
